(19) United States
(12) Patent Application Publication
(10) Pub. No.: US 2011/0133205 A1
(43) Pub. Date: Jun. 9, 2011

(54) FIELD-EFFECT TRANSISTOR

(75) Inventors: Tetsuzo Nagahisa, Osaka-shi (JP); John Kevin Twynam, Osaka-shi (JP)

(73) Assignee: Sharp Kabushiki Kaisha, Osaka-shi (JP)

(21) Appl. No.: 12/889,044

(22) Filed: Sep. 23, 2010

(30) Foreign Application Priority Data
Dec. 8, 2009 (JP) 2009-278727

(51) Int. Cl. H01L 29/78; H01L 29/205

(52) U.S. Cl. 257/76; 257/330; 257/E29.262; 257/E29.091

(57) ABSTRACT

A field-effect transistor provided with a channel layer, a carrier supply layer forming a heterojunction with the channel layer, a recessed portion recessed from a surface of the carrier supply layer, a first insulating layer formed at least along the recessed portion, a first gate electrode formed on the first insulating layer, a source electrode formed on one side of the recessed portion in a channel lengthwise direction, and a drain electrode formed on an opposite side of the recessed portion in the channel lengthwise direction. The recessed portion snakes in a direction intersecting the channel lengthwise direction, in the range of a channel length between the source electrode and the drain electrode.

### BACKGROUND OF THE INVENTION

This application claims priority under 35 U.S.C. §119(a) on Patent Application No. 2009-278727 filed in Japan on Dec. 8, 2009, the entire contents of which are herein incorporated by reference.

The present invention relates to a field-effect transistor, and more particularly to a field-effect transistor with a heterostructure.

Heterostructure field-effect transistors have attracted attention as key devices for next-generation power electronics. Demand for field-effect transistors with increased breakdown voltage and increased current capability has further grown.

FIG. 10 is a structural view of an example of a conventional HFET (Heterostructure Field-Effect Transistor) employing a heterojunction. The conventional HFET has a channel layer 111 and a carrier supply layer 112 sequentially formed on a substrate 110. A source electrode 121 and a drain electrode 122 are formed as electrodes on the carrier supply layer 112, and an insulating layer 131 is formed on the surface of the carrier supply layer 112. A gate electrode 123 is formed on the insulating layer 131, between the source electrode 121 and the drain electrode 122. The channel layer 111 is made of undoped GaN (gallium nitride), and the carrier supply layer 112 is made of n-type AlGaN (aluminum gallium nitride).

Electrons generated in the carrier supply layer 112 collect in the channel layer 111, and a channel composed of a two-dimensional electron gas layer (2DEG layer 115) is formed in a region on the channel layer 111 side in proximity to the interface between the channel layer 111 and the carrier supply layer 112. The 2DEG layer 115 is a high-mobility electron transit region that forms a channel for electrons to transit through. The density of the two-dimensional electron gas is controlled by the voltage applied to the gate electrode 123, thereby controlling the current flowing between the source electrode 121 and the drain electrode 122.

The conventional HFET performs a so-called normally-on operation that involves current continually flowing between the source electrode 121 and the drain electrode 122 when a voltage is not applied to the gate electrode 123. In recently years, field-effect transistors that perform a so-called normally-off operation that involves current not flowing between the source electrode 121 and the drain electrode 122 when a voltage is not applied to the gate electrode have been desired in the field of power electronics.

In light of this background, techniques that enable a normally-off operation to be realized in a high electron mobility transistor (HEMT) have been disclosed (e.g., see JP 2005-183733A).

FIG. 11A is a cross-sectional view of a conventional high electron mobility transistor. FIG. 11B is a structural plan view of the conventional high electron mobility transistor, showing a cross-section at C-C in FIG. 11A. Note that the same reference numerals are given to constituent elements having a similar function to the HFET shown in FIG. 10, and description thereof is omitted.

The high electron mobility transistor shown in FIG. 11A has a heterojunction structure between an electron transit layer (channel layer 111) made of a nitride compound semiconductor and an electron supply layer (carrier supply layer 112), a recess (recessed portion 113) is formed in the electron supply layer, and at least part of the upper surface of the electron transit layer corresponding to directly below the gate constitutes the bottom surface of the recess. Forming the recessed portion 113 increases the influence of the gate voltage on the 2DEG layer 115 and raises the threshold voltage. The conventional field-effect transistor reliably operates in normally-off mode, particularly in the case where the recessed portion 113 is recessed to the channel layer 111, given that the 2DEG layer 115 can be divided.

Note that with the conventional field-effect transistor, the gate electrode 123 filling the recessed portion 113 via the insulating layer 131 is parallelly opposed to the source electrode 121 and the drain electrode 122 in plan view, as shown in FIG. 11B. That is, the gate electrode 123 is formed in a direction orthogonal to the channel lengthwise direction, similarly to the source electrode 121 and the drain electrode 122, with the opposing surfaces of the gate electrode 123 and the source electrode 121 being parallel, and the opposing surfaces of the gate electrode 123 and the drain electrode 122 being parallel. Also, the recessed portion 113 is formed parallel in plan view. That is, both side surfaces of the recess of the recessed portion 113 are formed parallel to a direction orthogonal to the channel lengthwise direction.

Incidentally, reducing on-resistance (resistance between the source and drain electrodes in an on state) in comparison to conventional field-effect transistors is desired in the field of power electronics. Reducing on-resistance enables device power loss to be reduced. Also, reducing on-resistance enables device heat generation to be reduced, thus facilitating thermal design. Further increasing device breakdown voltage and current capability can therefore be realized.

In view of this, shortening the gate length in order to reduce on-resistance has been considered, and techniques for manufacturing short gate length field-effect transistors have been developed (e.g., see JP 2001-210658A). However, there is a limit to miniaturization techniques for shortening the device gate length due to factors such as the machining accuracy of manufacturing equipment, and the drop in threshold voltage due to short channel effect also becomes problematic as a result of shortening the gate length.

With a conventional field-effect transistor such as shown in FIGS. 11A and 11B (HFET, HEMT), further increasing device breakdown voltage and current capability cannot be realized, since on-resistance is not reduced. Also, while on-resistance can be reduced as a result of shortening the gate length, as shown in JP 2001-210658A, other problems arise such as the limit to device miniaturization and the drop in threshold voltage due to short channel effect.

The present invention has been made in order to solve the above problems, and has as an object to provide a field-effect transistor that enables on-resistance to be reduced, by providing a recessed portion having a snaking shape.

### SUMMARY OF THE INVENTION

A field-effect transistor according to the present invention is provided with a channel layer formed on a substrate, a carrier supply layer formed on the channel layer and forming a heterojunction with the channel layer, a recessed portion recessed from a surface of the carrier supply layer, a first insulating layer formed at least along the recessed portion, a first gate electrode formed on the first insulating layer, a source electrode formed on the carrier supply layer, on one side of a channel lengthwise based on the recessed portion, and a drain electrode formed on the carrier supply layer, on an opposite side of a channel lengthwise based on the recessed portion, with the recessed portion snaking in a direction intersecting the channel lengthwise direction, in a range of a channel length between the source electrode and the drain electrode. That is, the field-effect transistor according to the present invention is provided with the channel layer, the carrier supply layer, the recessed portion, the first insulating layer, the first gate electrode, the source electrode and the drain electrode, and the recessed portion is formed such that at least part thereof does not follow the direction of the channel width (hereinafter, orthogonal direction) orthogonal to the channel length between the source electrode and the drain electrode, in the range of the channel length between the source electrode and the drain electrode. Specifically, at least part of the recessed portion is angled relative to the direction of the channel width (hereinafter, orthogonal direction) orthogonal to the channel length between the source electrode and the drain electrode.

Accordingly, with the field-effect transistor according to the present invention, because the recessed portion is formed so as to have a snaking shape, the boundary length of the recessed portion (length in the channel widthwise direction) is greater than if the recessed portion were linearly formed in the orthogonal direction. In other words, according to the present invention, increasing the length of the boundary enables the resistance between the source electrode and the drain electrode to be reduced, and enables the current that flows when a constant voltage is applied to the first gate electrode to be increased.

In the above configuration, the recessed portion may be recessed to the channel layer. That is, the recessed portion may be formed in the carrier supply layer and the channel layer.

In this case, the 2DEG layer can be divided at the lower end of the recessed portion by dividing the carrier supply layer with the recessed portion, as a result of which the field-effect transistor can be reliably operated in normally-off mode.

In the above configuration, the recessed portion may extend at a constant width in plan view. That is, the recessed portion may be all the same width.

In this case, a field-effect transistor with stable characteristics can be obtained, since the optimum gate length can be maintained.

In the above configuration, the side surface of the recessed portion on the drain electrode side may be formed by connecting a plurality of bend portions, and an angle formed by the plurality of bend portions may be an obtuse angle.

In this case, the structure of the first gate electrode inhibits the concentration of electric field, as a result forming an obtuse angle even at the bend portions that bend toward the drain electrode side, thus enabling the strength of the electric field applied to the first gate electrode to be reduced.

In the above configuration, the side surface of the recessed portion on the drain electrode side may be formed by connecting a plurality of arc portions having a circular arc.

In this case, the structure of the first gate electrode inhibits the concentration of electric field as a result connecting the plurality of arc portions to form a smooth curve on the drain electrode side, thus enabling the strength of the electric field applied to the first gate electrode to be reduced.

In the above configuration, the first insulating layer may be provided with a surface insulating portion formed on the carrier supply layer, the first gate electrode may be provided with an electric field relaxation portion formed on the surface insulating portion, and a side surface of the electric field relaxation portion on the drain electrode side may be parallel to an opposing surface of the drain electrode opposed to the electric field relaxation portion.

In this case, the strength of the electric field applied to the first gate electrode can be reduced, given that the structure of the electric field relaxation portion inhibits the concentration of electric field as a result of being parallelly opposed to the drain electrode. Also, since the electric field relaxation portion enables the contact area between the first gate electrode and the first insulating layer to be secured, delamination is inhibited and yield can be improved.

In the above configuration, the field-effect transistor may be provided with a second insulating layer formed on the carrier supply layer, and a second gate electrode formed on the first gate electrode, and the second gate electrode may project further to the drain electrode side than the first gate electrode.

In this case, forming the second gate electrode enables concentration of the electric field applied to the lower part of the first gate electrode to be relaxed by distributing electric field concentrated in the lower part of the first gate electrode to the second gate electrode.

In the above configuration, the side surface of the second gate electrode on the drain electrode side may be parallel to an opposing surface of the drain electrode opposed to the second gate electrode.

In this case, the strength of the electric field applied to the second gate electrode can be reduced, given that the structure of the second gate electrode inhibits the concentration of electric field as a result of being parallelly opposed to the drain electrode.

In the above configuration, the channel layer may be made of GaN, and the carrier supply layer may be made of AlGaN.

In this case, heat dissipation is favorable given the high electron saturation velocity, high breakdown voltage and high heat conductivity resulting from employing a nitride compound semiconductor, enabling a field-effect transistor that can operate at high temperature and does not contain harmful substances to be provided.

In the above configuration, the first gate electrode may be formed in the recessed portion.

In this case, a field-effect transistor with stable characteristics is obtained, since the shape of the first gate electrode can be optimized.

### BRIEF DESCRIPTION OF THE DRAWINGS

FIG. 1A is a cross-sectional view of a field-effect transistor according to Embodiment 1 of the present invention.

FIG. 1B is a structural plan view showing a cross-section at A-A in FIG. 1A.

FIG. 1C is a plan view of the field-effect transistor shown in FIG. 1A.

FIG. 2 is a structural plan view showing Variation 1 of the cross-section at A-A in FIG. 1A.

FIG. 3 is a structural plan view showing Variation 2 of the cross-section at A-A in FIG. 1A.

FIG. 4 is a schematic diagram representing in plan view the main current path between a source electrode and a drain electrode in FIG. 11B.

FIG. 5 is a schematic diagram representing in plan view the main current path between a source electrode and a drain electrode in FIG. 1B.

FIG. 6 is a schematic diagram representing in plan view the main current path between a source electrode and a drain electrode in FIG. 2.

FIG. 7 is a schematic diagram representing in plan view the main current path between a source electrode and a drain electrode in FIG. 3.

FIG. 8 is a characteristic chart of resistance values obtained by simulation.

FIG. 9A is a cross-sectional view of a field-effect transistor according to Embodiment 2 of the present invention.

FIG. 9B is a structural plan view of a cross-section at B-B in FIG. 9A.

FIG. 9C is a plan view of the field-effect transistor shown in FIG. 9A.

FIG. 10 is a structural view of an example of a conventional HFET employing a heterojunction.

FIG. 11A is a cross-sectional view of a conventional high electron mobility transistor.

FIG. 11B is a structural plan view showing a cross-section at C-C in FIG. 11A.

### DESCRIPTION OF REFERENCE NUMERALS

1, 2 Field-effect Transistor
10, 110 Substrate
11, 111 Channel Layer
12, 112 Carrier Supply Layer
13, 113 Recessed Portion
15, 115 2DEG Layer
21, 121 Source Electrode
22, 122 Drain Electrode
23, 23d, 123 First Gate Electrode
23a Electric Field Relaxation Portion
24 Second Gate Electrode
25 Lower Region
31 First Insulating Layer
31a Surface Insulating Portion
32 Second Insulating Layer
131 Insulating Layer

### DESCRIPTION OF THE PREFERRED EMBODIMENTS

### Embodiment 1

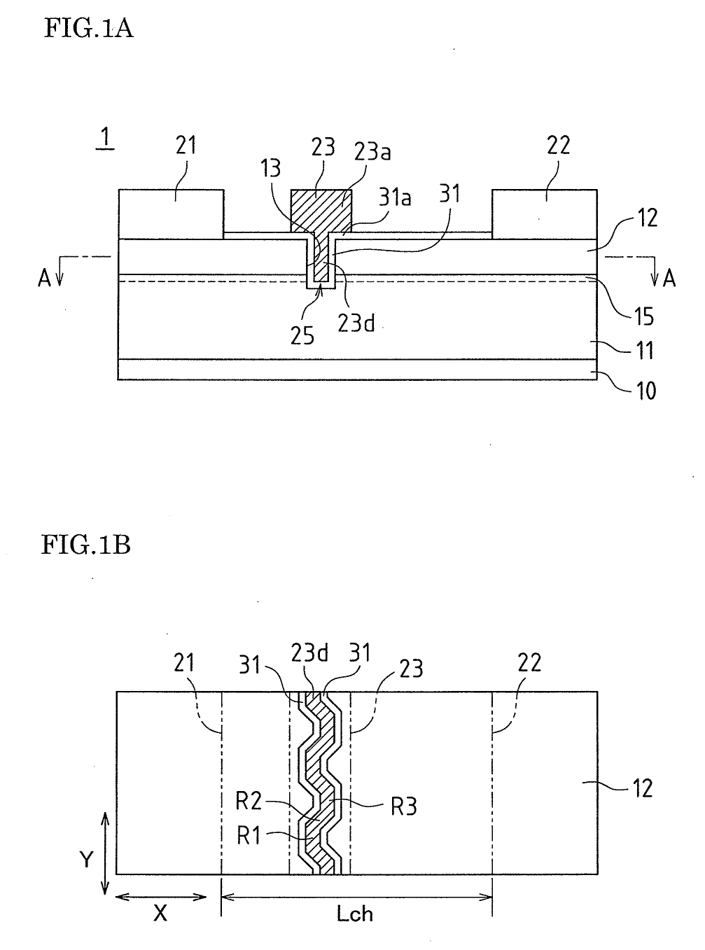

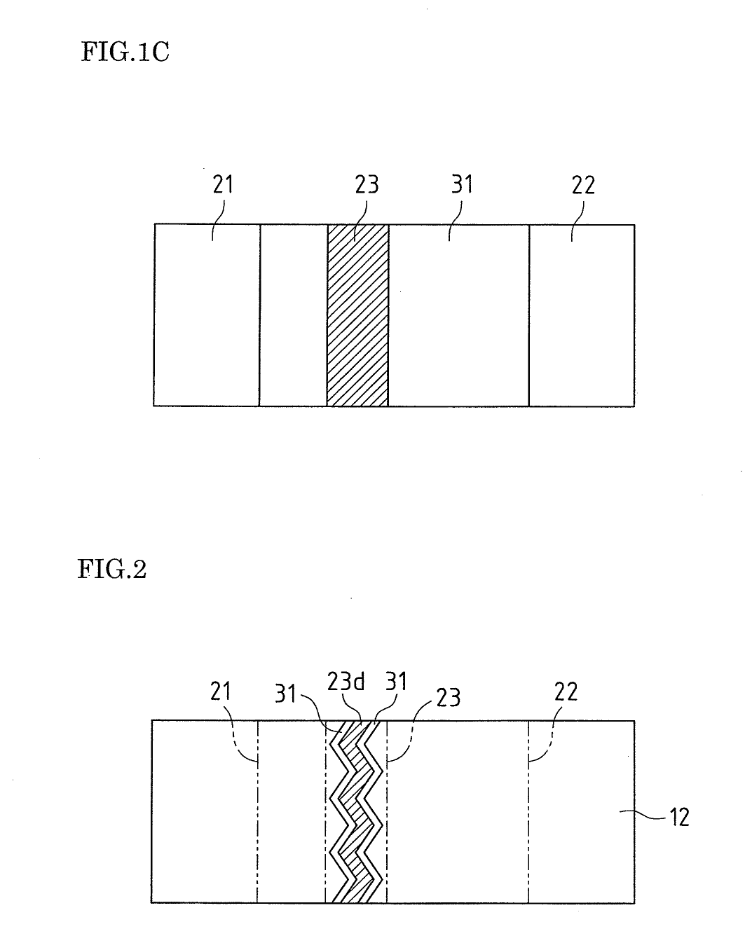

A field-effect transistor according to Embodiment 1 of the present invention will be described based on FIGS. 1A to 1C.

FIG. 1A is a cross-sectional view of the field-effect transistor according to Embodiment 1 of the present invention. FIG. 1B is a structural plan view showing a cross-section at A-A in FIG. 1A. FIG. 1C is a plan view of the field-effect transistor shown in FIG. 1A. Note that while hatching indicating electrodes has been omitted for ease of viewing, the principal part (first gate electrode 23) has been hatched.

A field-effect transistor 1 according to the present embodiment is provided with a channel layer 11 formed on a substrate 10, a carrier supply layer 12 formed on the channel layer 11 and forming a heterojunction with the channel layer 11, a recessed portion 13 recessed from a surface of the carrier supply layer 12, a first insulating layer 31 formed along the carrier supply layer 12 and the recessed portion 13 in the range of a channel length Lch, a first gate electrode 23 formed on the first insulating layer 31, a source electrode 21 formed on the carrier supply layer 12, on one side of a channel lengthwise direction X based on the recessed portion 13, and a drain electrode 22 formed on the carrier supply layer 12, on an opposite side of a channel lengthwise direction X based on the recessed portion 13.

Opposing edges (see FIG. 1B, etc.) of the source electrode 21 and the drain electrode 22 are parallel. Also, the recessed portion 13 extends in a direction orthogonal to the channel lengthwise direction X while snaking in the range of the channel length Lch across which the source electrode 21 and the drain electrode 22 are parallelly opposed. That is, the recessed portion 13 extends while snaking in a direction (channel widthwise direction Y) orthogonal to the channel length Lch between the source electrode 21 and the drain electrode 22. Specifically, at least part of the recessed portion 13 (see R2 shown in FIG. 1B) is angled, so as to not follow the direction of the channel width orthogonal to the channel length Lch (hereinafter, also referred to as the channel widthwise direction). Hereinafter, the direction orthogonal to the channel lengthwise direction X will be referred to as the channel widthwise direction Y. Thus, because the recessed portion 13 has a snaking shape, the boundary length of the recessed portion 13 (length in the channel widthwise direction Y) is greater than if the recessed portion 13 were linearly formed in the channel widthwise direction. In other words, increasing the length of the boundary (length in the channel widthwise direction) enables the resistance between the source electrode 21 and the drain electrode 22 to be reduced, and enables the current that flows when a constant current is applied to the first gate electrode 23 to be increased.

Hereinafter, the various constituent elements will be described in detail.

The substrate 10 is a Si substrate. Note that the substrate 10 can be any substrate, provided it is lattice matched to some extent to the channel layer 11, and may alternatively be a sapphire substrate, a SiC substrate or a GaN substrate, for example.

The channel layer 11 and the carrier supply layer 12 form a heterojunction, and electrons generated in the carrier supply layer 12 collect in the channel layer 11, with a channel composed of a two-dimensional electron gas layer being formed as a 2DEG layer 15 in a region on the channel layer 11 side of the interface between the channel layer 11 and the carrier supply layer 12. The 2DEG layer 15 is a high-mobility electron transit region that forms a channel for electrons to transit through.

In other words, the 2DEG layer 15 is formed at the interface between the channel layer 11 and the carrier supply layer 12, as a channel through which electrons flow between the source electrode 21 and the drain electrode 22. The current flowing in the field-effect transistor 1 can be controlled by the voltage applied to the first gate electrode 23.

The channel layer 11 is made of GaN, and the carrier supply layer 12 is made of AlGaN. Accordingly, heat dissipation is favorable given the high electron saturation velocity, high breakdown voltage and high heat conductivity resulting from employing a nitride compound semiconductor, enabling a field-effect transistor that can operate at high temperature and does not contain harmful substances to be provided.

Note that if the channel layer 11 and the carrier supply layer 12 form a heterojunction, the layers can be formed by appropriately selecting the elements constituting the layers and the composition ratio of the elements. Example combinations include Al_{0.1}Ga_{0.9}N/Al_{0.3}GaN_{0.7} and GaN/AlGaInN (aluminum gallium indium nitride) (the layers are laminated with the compound on the left of the slash (“/”) as the lower layer and compound on the right as the upper layer).

The source electrode 21 and the drain electrode 22 are made of Ti/Al/Au (titanium/aluminum/gold). Note that any material can be used for the source electrode 21 and the drain electrode 22, provided it is a metal exhibiting conductivity and makes an ohmic contact to the carrier supply layer 12.

The first insulating layer 31 is made of SiO2. Note that any material can be used for the first insulating layer 31, provided it has insulating properties, examples of which include SiO (silicon nitride), Al₂O₃ (alumina), HfOₓ (hafnium oxide) and AlN (aluminum nitride).

The first gate electrode 23 is made of WN/Au (tungsten nitride/gold). Note that any material can be used for the first gate electrode 23, provided it is a metal exhibiting conductivity and has adhesiveness with the first insulating layer 31.

The first gate electrode 23 fills the recessed portion 13. That is, the first gate electrode 23 extends in the recessed portion 13. Note that in the present embodiment, the first gate electrode 23 formed in the recessed portion 13 will be denoted as a first gate electrode 23d for ease of description. Also, the portion of the current path between the source electrode and the drain electrode corresponding to the bottom surface of the first gate electrode 23d is referred to as a lower region 25. By thus forming the first gate electrode 23 (specifically, first gate electrode 23d) in the recessed portion 13, a field-effect transistor with stable characteristics can be obtained, since the shape of the first gate electrode 23 can be optimized.

The recessed portion 13 desirably is recessed to the channel layer 11. That is, the recessed portion 13 desirably is formed in the carrier supply layer 12 and the channel layer 11. In this case, the 2DEG layer 15 can be divided by the lower end of the recessed portion 13 by dividing the carrier supply layer 12 with the recessed portion 13, as a result of which the field-effect transistor can reliably operate in normally-off mode.

Also, the recessed portion 13 desirably extends at a constant width in plan view. That is, as shown in FIG. 1B, the recessed portion 13 desirably is all the same width. In this case, a field-effect transistor with stable characteristics can be obtained, since an optimum gate length can be maintained.

With a field-effect transistor, the resistance between the source electrode and the drain electrode increases when the gate length increases. On the other hand, in the case where the gate length is shortened, a drop in yield due to the difficulty in controlling microfabrication and a drop in threshold voltage due to short channel effect become problematic. Thus, fixing the gate length is desirable in order to stabilize device characteristics.

The layout of the recessed portion 13 in plan view has a snaking shape, as shown in FIG. 1B. The recessed portion 13, in plan view, is formed by the regions R1 and R3 formed in the channel widthwise direction Y being connected by a region R2 formed between the regions R1 and R3 at an angle to the channel lengthwise direction X and the channel widthwise direction Y. Due to the regions R1 to R3 being connected, the shape of the recessed portion 13 is composed of consecutive trapezoids in plan view, as a result of which the recessed portion 13 has a snaking shape that zigzags in the channel widthwise direction Y.

The first insulating layer 31 is provided with a surface insulating portion 31a formed on the carrier supply layer 12, the first gate electrode 23 is provided with a electric field relaxation portion 23a extending over the surface insulating portion 31a, and the side surface of the electric field relaxation portion 23a on the drain electrode 22 side is parallelly opposed to the drain electrode 22 in plan view. Accordingly, the strength of the electric field applied to the first gate electrode 23 can be reduced, given that the structure of the electric field relaxation portion 23a inhibits the concentration of electric field, as a result of being parallelly opposed to the drain electrode 22. Also, since the electric field relaxation portion 23a enables the contact area between the first gate electrode 23 and the first insulating layer 31 to be secured, delamination is inhibited and yield can be improved.

Also, a buffer layer made of GaN grown at a low temperature may be formed between the substrate 10 and the channel layer 11. Forming the buffer layer enables the crystallinity of the channel layer 11 to be improved, and enables the breakdown voltage in the depth direction to be improved.

Also, a spacer layer may be formed between the channel layer 11 and the carrier supply layer 12. Forming the spacer layer enables electron mobility in the 2DEG layer 15 to be improved. The spacer layer is made of a material such as AlN, AlInN (aluminum indium nitride) or AlGaInN, for example.

Also, a cap layer may be formed on the carrier supply layer 12. Forming the cap layer enables oxidation of the carrier supply layer 12 and the introduction of impurities to be prevented. The cap layer is made of a material such as GaN, for example.

Also, a contact layer made of GaN doped with Si at a level of 10¹⁹/cm³ may be formed on the carrier supply layer 12. Forming the contact layer enables the carrier supply layer 12 to readily make an ohmic contact to the source electrode 21 and the drain electrode 22.

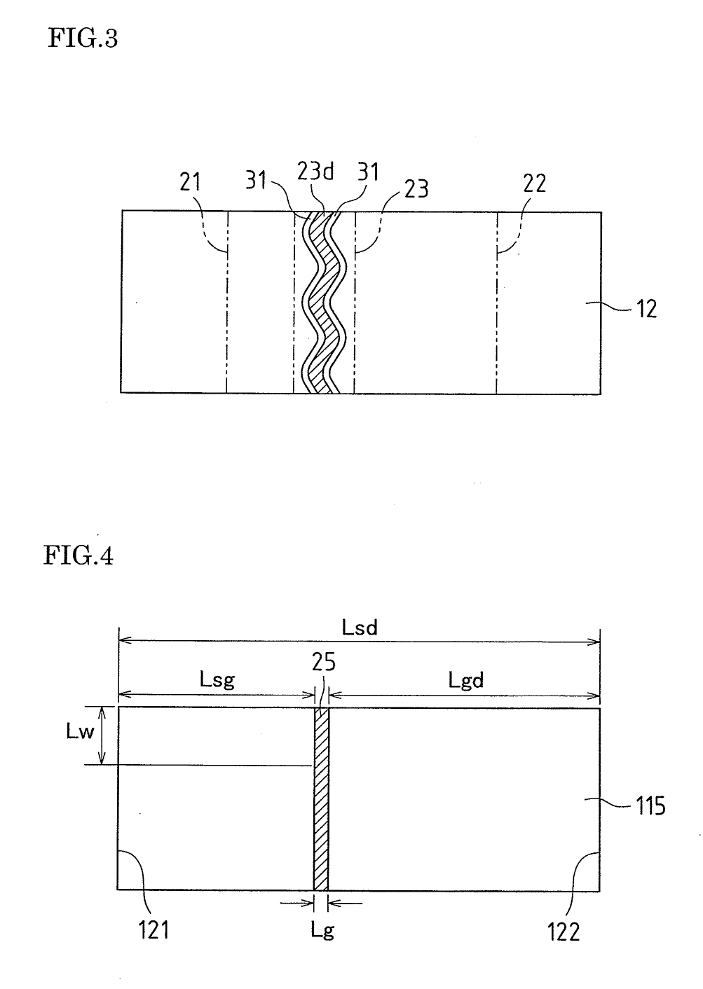

While FIG. 1B is given as an example layout, the recessed portion 13, may take other shapes. For example, the recessed portion 13 may take the shapes shown in FIG. 2 (Variation 1) and FIG. 3 (Variation 2).

The side surface of the recessed portion 13 on the drain electrode 22 side is formed by connecting a plurality of bend portions in plan view, with the angle formed by the plurality of bend portions being an obtuse angle. Accordingly, the structure of the first gate electrode 23 inhibits the concentration of electric field, as a result of forming an obtuse angle even at the bend portions that bend toward the drain electrode 22 side, thus enabling the strength of the electric field applied to the first gate electrode 23 to be reduced.

FIG. 2 is a structural plan view showing Variation 1 of the cross-section at A-A in FIG. 1A. This is Variation 1 of the layout of the recessed portion 13 in plan view, with the recessed portion 13 having a triangular wave shape formed by connecting the bend portions. Note that different from the recessed portion 13 shown in FIG. 1B, the recessed portion 13 shown in FIG. 2 does not have any regions formed in the channel widthwise direction Y (see region R3 of the recessed portion 13 shown in FIG. 1B).

Also, the side surface of the recessed portion 13 on the drain electrode 22 side may be formed by connecting a plurality of arc portions having a circular arc in plan view (see FIG. 7). A similar effect to Variation 1 is also obtained with the above shape.

FIG. 3 is a structural plan view showing Variation 2 of the cross-section at A-A in FIG. 1A. This is Variation 2 of the layout of the recessed portion 13 in plan view, with the recessed portion 13 having a sinusoidal shape formed by connecting the arc portions. Note that different from the recessed portion 13 shown in FIG. 1B, the recessed portion 13 shown in FIG. 3 does not have any regions formed in the channel widthwise direction Y (see region R3 of the recessed portion 13 shown in FIG. 1B).

Next, the manufacturing method of the field-effect transistor 1 according to the present embodiment will be described.

A channel layer 11 made of GaN having a film thickness of 2 μm and a carrier supply layer 12 made of AlGaN having a film thickness of 30 nm are deposited one upon the other on a substrate 10 by metalorganic CVD (MOCVD).

Next, a source electrode 21 and a drain electrode 22 each having a film thickness of 200 nm are vapor deposited on the carrier supply layer 12, and an ohmic contact is made to the carrier supply layer 12. The interval between the source electrode 21 and the drain electrode 22 is adjusted according to the desired performance of the field-effect transistor 1. The manufacturing method of the source electrode 21 and the drain electrode 22 is not particularly limited, and a known method can be used.

The surface of the carrier supply layer 12 is recessed by 35 nm to form the recessed portion 13. The depth to which the surface of the carrier supply layer 12 is recessed is not particular limited, and can be appropriately selected. In the present embodiment, reactive ion etching (RIE) is performed to form the recessed portion 13, but the formation method of the recessed portion 13 is not particular limited, and a known method can be used.

A first insulating layer 31 having a film thickness of 20 nm is formed on the recessed portion 13 with a known method. If the first gate electrode 23 and the recessed portion 13 are insulated from each other, the first insulating layer 31 desirably is relatively thin. This is because the threshold voltage of the field-effect transistor 1 decreases when the thickness of the first insulating layer 31 increases, preventing the field-effect transistor from operating in normally-off mode.

A first gate electrode 23 having a film thickness of 200 nm is formed on the first insulating layer 31 with a known method such as vapor deposition. At this time, a first gate electrode 23d is formed to fill the recessed portion 13.

### Simulation Results

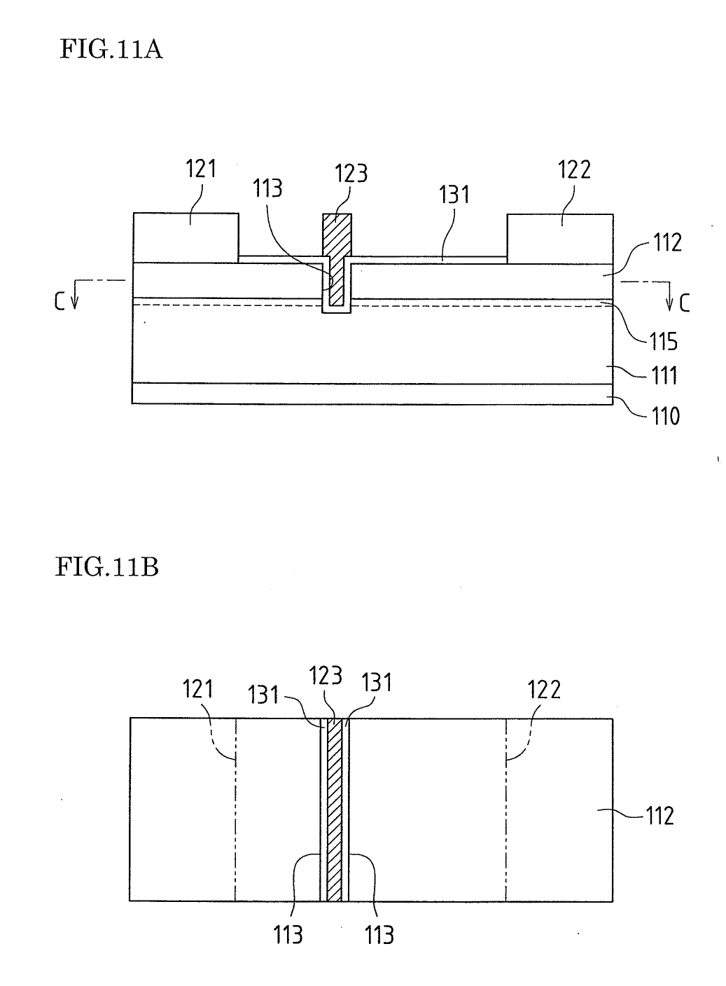

Here, on-resistance values in the case where the recessed portion has a linear shape as with the conventional example shown in FIG. 11B, and in the case where the recessed portion has a snaking shape as in FIGS. 1B, 2 and 3 were simulated and compared, the results of which are shown below.

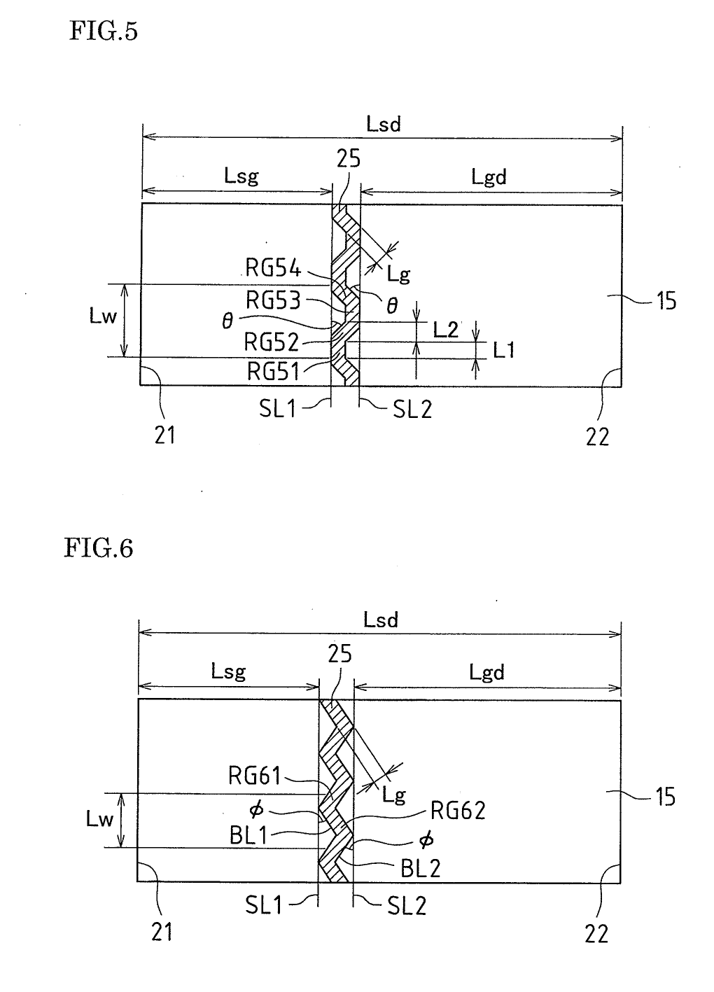

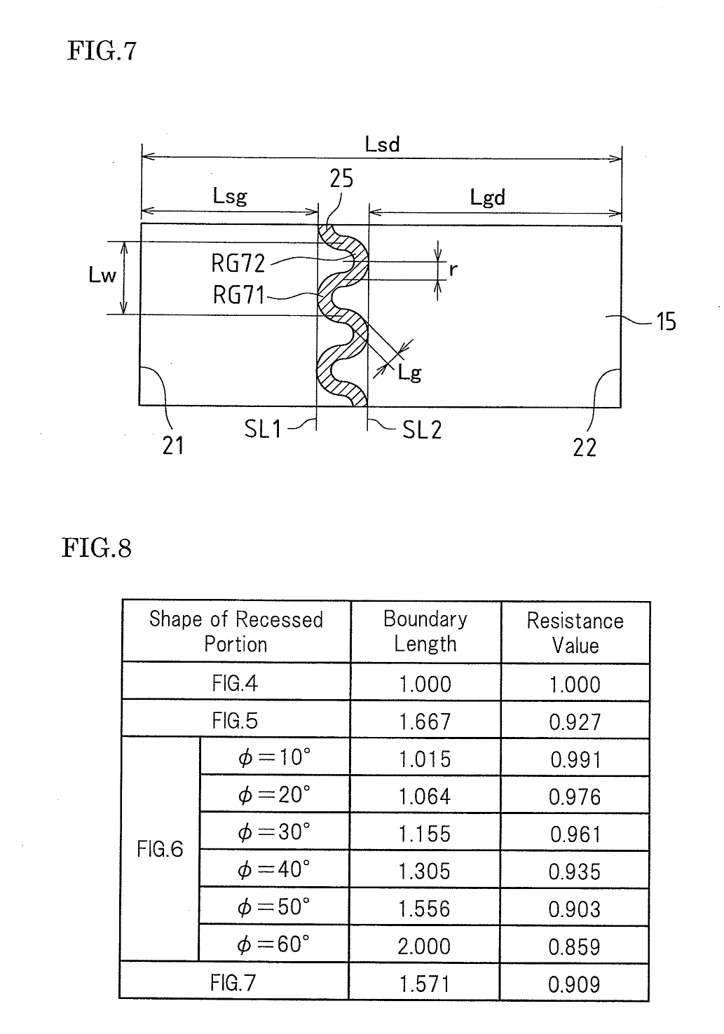

The simulation conditions will be described based on FIGS. 4 to 7.

FIG. 4 is a schematic diagram representing in plan view the main current path between the source electrode and the drain electrode in FIG. 11B, or in other words, the case where the recessed portion has a linear shape. FIG. 5 is a schematic diagram representing in plan view the main current path between the source electrode and the drain electrode in FIG. 1B, or in other words, the case where the recessed portion has a trapezoidal shape as in Embodiment 1. FIG. 6 is a schematic diagram representing in plan view the main current path between the source electrode and the drain electrode in FIG. 2, or in other words, the case where the recessed portion has a triangular wave shape as in Variation 1. FIG. 7 is a schematic diagram representing in plan view the main current path between the source electrode and the drain electrode in FIG. 3, or in other words, the case where the recessed portion has a sinusoidal shape as in Variation 2. Note that the same reference numerals are given to constituent elements having a similar function to FIGS. 1B, 2, 3 and 11B, and description thereof will be omitted. Also, the 2DEG layer 115 in FIG. 4 is equivalent to the 2DEG layer 15 in FIGS. 5 to 7, the source electrode 121 in FIG. 4 is equivalent to the source electrode 21 in FIGS. 5 to 7, and the drain electrode 122 in FIG. 4 is equivalent to the drain electrode 22 in FIGS. 5 to 7.

The shaded region in each of FIGS. 4 to 7 is the lower region 25, and the region other than the lower region 25 is assumed to be the 2DEG layer 15. In the simulation, the resistivity in the lower region 25 was set to twenty times the 2DEG layer 15. Note that the lower region 25 in each of FIGS. 4 to 7 corresponds to the bottom surface of the gate electrode 123.

The left edge in FIGS. 4 to 7 corresponds to the source electrode 21 side edge, and the right edge in FIGS. 4 to 7 corresponds to the drain electrode 22 side edge. In FIGS. 5 to 7, a supplementary line SL1 and a supplementary line SL2 are drawn, with the lower region 25 being formed between the supplementary line SL1 and the supplementary line SL2. In FIG. 4, the lower region 25 extends linearly in the channel widthwise direction Y at a constant groove width Lg. In FIGS. 5 to 7, the lower region 25 extends in the channel widthwise direction Y at the constant groove width Lg.

In FIGS. 4 to 7, the distance between the source electrode 21 and the drain electrode 22 is given as a distance Lsd, the distance between the source electrode 21 and the supplementary line SL1 is given as a distance Lsg, and the distance between the drain electrode 22 and the supplementary line SL2 is given as a distance Lgd. Note that in FIG. 4, the edge of the lower region 25 on the source electrode 21 side corresponds to the supplementary line SL1, and the edge of the lower region 25 on the drain electrode 22 side corresponds to the supplementary line SL2. In FIGS. 5 to 7, the lower region 25 has a cyclic shape in the channel widthwise direction Y.

In FIG. 5 (Embodiment 1), a single cycle is constituted by a region RG51 of the lower region 25 along the supplementary line SL1, a region RG52 that approaches the supplementary line SL2 from the region RG51 at an θ angle of inclination to the supplementary line SL1, a region RG53 along the supplementary line SL2, and a region RG54 that approaches the supplementary line SL1 from the region RG53 at an θ angle of inclination to the supplementary line SL2, with the length of a single cycle in the channel widthwise direction Y being given as a cycle Lw.

The length of the regions RG51 and RG53 in the channel widthwise direction Y is given as a distance L1, and the length of the regions RG52 and RG54 in the channel widthwise direction Y is given as a distance L2, with the distance L2 being twice the distance L1. The θ angle of inclination is 60 degrees.

In FIG. 6 (Variation 1), a single cycle is constituted by a wedge region RG61 of the lower region 25 that projects on the source electrode 21 side and a wedge region RG62 that projects on the drain electrode 22 side, with the length of a single cycle in the channel widthwise direction Y being given as a cycle Lw.

The tip of the region RG61 contacts the supplementary line SL1, and the tip of the region RG62 contacts the supplementary line SL2. A boundary line BL1 that reaches from the tip of the region RG61 forms an φ angle of inclination with the supplementary line SL1, and a boundary line BL2 that reaches from the tip of the region RG62 forms an φ angle of inclination with the supplementary line SL2.

In FIG. 6, simulation was performed for shapes whose φ angle of inclination was from 10 degrees to 60 degrees (in 10 degree intervals) (see FIG. 8).

In FIG. 7 (Variation 2), a single cycle is constituted by a semicircular arc region RG71 of the lower region 25 that projects on the source electrode 21 side and a semicircular arc region RG72 that projects on the drain electrode 22 side, with the length of a single cycle in the channel widthwise direction Y being given as a cycle Lw.

The tip of the region RG71 contacts the supplementary line SL1, and the tip of the region RG72 contacts the supplementary line SL2. The region RG71 and the region RG72 have a radius r of 0.5 μm, where the radius r is the distance from the center of the circular arc to the center of the groove width Lg.

In FIGS. 4 to 7, the distance Lg is 0.5 μm, the distance Lsd is 6 μm, the distance Lsg is 1 μm, and the cycle Lw is 2 μm. The distance Lgd changes depending on the simulation conditions.

The on-resistance value between the source electrode and the drain electrode per cycle Lw and the length of the boundary corresponding to the cycle Lw with the above settings configured as the simulation conditions were calculated.

FIG. 8 is a characteristic chart of resistance values obtained by simulation. Note that each of the resistance values is standardized with the resistance value in FIG. 4 as 1, and the boundary length is standardized with the boundary length in FIG. 4 as 1.

With the shape in FIG. 5, the boundary length was 1.667 and the resistance value was 0.927. With the shape in FIG. 6, the boundary length was 1.015 and the resistance value was 0.991 when the φ angle of inclination was 10 degrees, and the boundary length was 2.000 and the resistance value was 0.859 when the φ angle of inclination was 60 degrees. The boundary length increased and the resistance value decreased with increases in the φ angle of inclination. With the shape in FIG. 7, the boundary length was 1.571, and the resistance value was 0.909.

FIG. 8 reveals that on-resistance is reduced with any of the shapes in FIGS. 5 to 7. Also, with the shape in FIG. 6, on-resistance is reduced the greater the φ angle of inclination.

### Embodiment 2

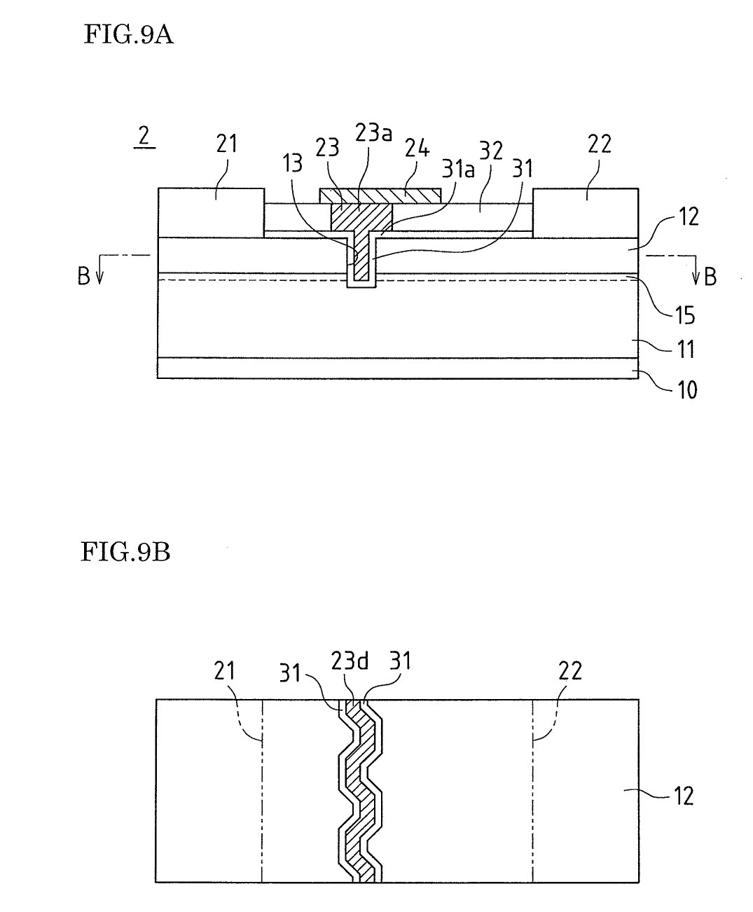

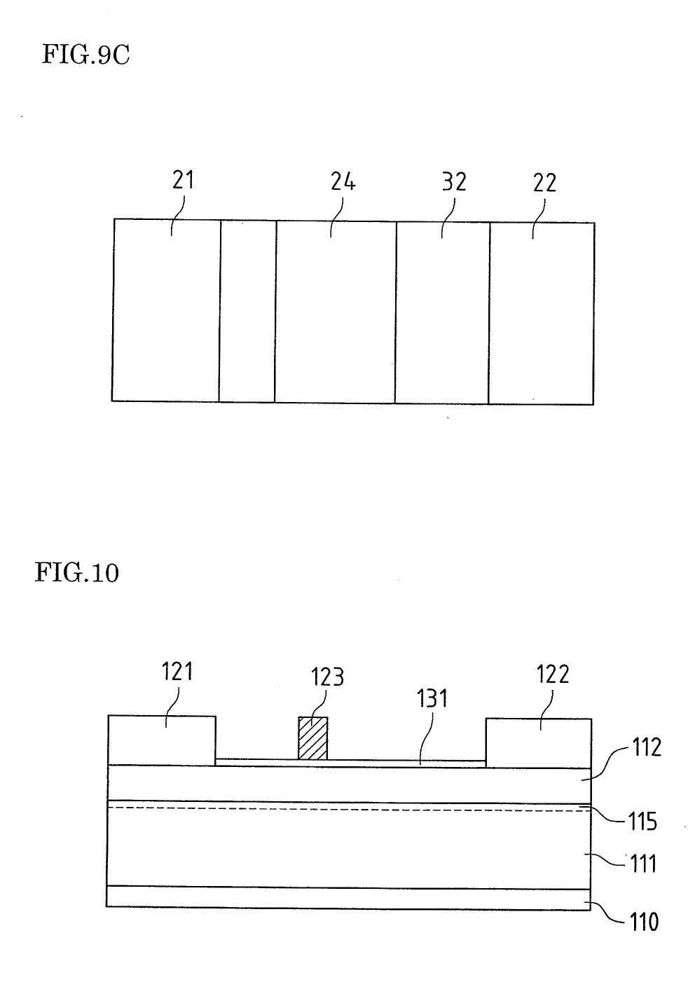

A field-effect transistor according to Embodiment 2 of the present invention will be described based on FIGS. 9A to 9C. Note that the same reference numerals are given to constituent elements having a similar function to Embodiment 1, and description thereof will be omitted.

FIG. 9A is a cross-sectional view of a field-effect transistor according to Embodiment 2 of the present invention. FIG. 9B is a structural plan view of the field-effect transistor, showing a cross-section at B-B in FIG. 9A. FIG. 9C is a plan view of the field-effect transistor shown in FIG. 9A. Note that that while hatching has been omitted for ease of viewing, the principal parts (first gate electrode 23, second gate electrode 24) have been hatched.

A field-effect transistor 2 according to present embodiment is provided with a channel layer 11 formed on a substrate 10, a carrier supply layer 12 formed on the channel layer 11 and forming a heterojunction with the channel layer 11, a recessed portion 13 recessed from a surface of the carrier supply layer 12, a first insulating layer 31 formed along the recessed portion 13, a first gate electrode 23 formed on the first insulating layer 31, a source electrode 21 formed on the carrier supply layer 12, on one side of a channel lengthwise direction based on the recessed portion, and a drain electrode 22 formed on the carrier supply layer 12, on an opposite side of the channel lengthwise direction based on the recessed portion.

The recessed portion 13 extends (is formed) in a direction orthogonal to the channel lengthwise direction while snaking in the range of the channel length between the source electrode 21 and the drain electrode 22 whose opposing edges (opposing surfaces) are parallel.

The field-effect transistor 2 according to present embodiment is provided with a second insulating layer 32 formed on the carrier supply layer 12, and a second gate electrode 24 formed on at least the first gate electrode 23 (specifically, the first gate electrode 23 and the second insulating layer 32). The second gate electrode 24 projects further to the drain electrode 22 side than the first gate electrode 23. Forming the second gate electrode 24 thus enables concentration of the electric field applied to the lower part of the first gate electrode 23 to be relaxed, by distributing electric field concentrated in the lower part of the first gate electrode 23 to the second gate electrode 24.

The side surface of the second gate electrode 24 on the drain electrode 22 side is opposed to the side surface of the drain electrode 22, and these surfaces are parallel. Accordingly, the strength of the electric field applied to the second gate electrode 24 can be reduced, given that the structure of the second gate electrode 24 inhibits the concentration of electric field as a result of being parallelly opposed to the drain electrode 22.

The second insulating layer 32 is made of SiN having a film thickness of 200 nm. Note that any material can be used for the second insulating layer 32, provided it has insulating properties, examples of which include SiO₂, Al₂O₃, HfOx and AlN. Also, the second gate electrode 24 desirably employs a material with a high dielectric constant, in order to reduce the strength of the electric field concentrated in the second gate electrode 24.

The second gate electrode 24 is made of Au having a film thickness of 200 nm. Note that any material can be used for the second gate electrode 24, provided it is a metal exhibiting conductivity and has adhesion with the first gate electrode 23 and the second insulating layer 32. Also, the first gate electrode 23 and the second gate electrode 24 may be formed consecutively, after forming the first insulating layer 31 and the second insulating layer 32.

In the present embodiment, the field-effect transistor may be configured such that the first insulating layer 31 is only formed in proximity to the first gate electrode 23. In this case, the second gate electrode 24 and the carrier supply layer 12 are insulated by the second insulating layer 32.

Embodiments for implementing the present invention have been described above, but the invention is not limited by the foregoing embodiments, and can be variously modified within the scope defined by the claims. Embodiments obtained by appropriately combining technical means respectively set forth in the different embodiments are also encompassed in the technical scope of the invention.

What is claimed is:

1. A field-effect transistor comprising:
a channel layer formed on a substrate;
a carrier supply layer formed on the channel layer and forming a heterojunction with the channel layer;
a recessed portion recessed from a surface of the carrier supply layer;
a first insulating layer formed at least along the recessed portion;
a first gate electrode formed on the first insulating layer;
a source electrode formed on the carrier supply layer, on one side of a channel lengthwise based on the recessed portion; and
a drain electrode formed on the carrier supply layer, on an opposite side of a channel lengthwise based on the recessed portion,
wherein the recessed portion snakes in a direction intersecting the channel lengthwise direction, in a range of a channel length between the source electrode and the drain electrode.

2. The field-effect transistor according to claim 1, wherein the recessed portion is recessed to the channel layer.

3. The field-effect transistor according to claim 1, wherein the recessed portion has a constant width in plan view.

4. The field-effect transistor according to claim 1,
wherein a side surface of the recessed portion on the drain electrode side is formed by connecting a plurality of bend portions, and
an angle formed by the plurality of bend portions is an obtuse angle.

5. The field-effect transistor according to claim 1, wherein a side surface of the recessed portion on the drain electrode side is formed by connecting a plurality of arc portions having a circular arc.

6. The field-effect transistor according to claim 1,
wherein the first insulating layer is provided with a surface insulating portion formed on the carrier supply layer,
the first gate electrode is provided with an electric field relaxation portion formed on the surface insulating portion, and
a side surface of the electric field relaxation portion on the drain electrode side is parallel to an opposing surface of the drain electrode opposed to the electric field relaxation portion.

7. The field-effect transistor according to claim 1, comprising
a second insulating layer formed on the carrier supply layer; and
a second gate electrode formed on the first gate electrode,
wherein the second gate electrode projects further to the drain electrode side than the first gate electrode.

8. The field-effect transistor according to claim 7, wherein a side surface of the second gate electrode on the drain electrode side is parallel to an opposing surface of the drain electrode opposed to the second gate electrode.

9. The field-effect transistor according to claim 1, wherein the channel layer is made of GaN, and the carrier supply layer is made of AlGaN.

10. The field-effect transistor according to claim 1, wherein the first gate electrode is formed in the recessed portion.
